(19) United States
(12) Patent Application Publication
(10) Pub. No.: US 2024/0192260 A1
(43) Pub. Date: Jun. 13, 2024

(54) System for Monitoring the Status of a Line in an Energy Chain

(71) Applicant: igus GmbH, Köln (DE)

(72) Inventor: Richard Habering, Köln (DE)

(21) Appl. No.: 18/286,113

(22) PCT Filed: Apr. 7, 2022
(86) PCT No.: PCT/EP2022/059342

§ 371 Date: Oct. 7, 2023

(30) Foreign Application Priority Data
Apr. 12, 2021 (DE) 20 2021 101 964.6
Nov. 23, 2021 (DE) 20 2021 106 364.5

(51) Int. Cl. G01R 31/08

(52) U.S. Cl. CPC G01R 31/085

(57) ABSTRACT

A monitoring system includes a line guiding device (1; 41) with a movable section and at least one line (13) with a line section (130) to be monitored, guided by the line guiding device (1; 41), and a monitoring device (10) with a first (200A) and a second (200B) module located on respective ends of the line section to be monitored. In at least one embodiment, the modules (200A, 200B) are designed to work together to determine an electrical transmission property of the line section (13A; 13B) with respect to a predetermined radio frequency (RF) signal. The first module (200A) includes an RF generator coupled to the line (13) to be monitored to couple a predetermined RF signal onto the line section (130) as a test signal. The second module (200B) has an RF receiver coupled to the line to be monitored to receive the RF signal out of the line section (130) and evaluate properties of the received RF signal to determine at least one value relating to the transmission quality over the line section (130).

The invention relates generally to the field of monitoring the status of an electrical line, in particular a line that is guided by a dynamic line guiding device such as, e.g., an energy chain or the like, in order to power a movable consumer. The invention relates in particular to the monitoring of moving lines.

A limited service life and possibly a resulting failure of such a line, e.g., of a supply line for data and/or for power supply, is unavoidable due to the application-specific movement and can lead to critical situations and high costs.

The invention relates in particular to a system and method for monitoring line status during actual operation of the line, comprising a monitoring device which has a first module and a second module, which are each provided, e.g., connected or coupled, on both sides of a line section to be monitored. This is typically arranged in a movable line guiding device for the protected guiding of at least the monitored line, wherein the line guiding device has at least one movable section between a first connection point and a second connection point, movable relative thereto, through which the line section which is to be monitored because it is stressed by movement is guided.

Such a generic system was proposed, e.g., in WO 2020/104491 A1 of the applicant. Here, two modules are provided at the ends of the line section to be monitored. These modules each use properties of a protocol layer of a digital data transmission protocol in order to carry out a status monitoring. A disadvantage here is that, with this concept, only those lines can be monitored which are intended for such a digital data protocol, e.g., ETHERNET, or are at least also sufficiently suitable. Furthermore, by the system, possibly the actual data transmission—because the protocol properties thereof are to be used—is at least slightly affected by additional data, which are only transmitted for testing or monitoring the status of the line.

A solution for the on-line monitoring of the line status during operation without affecting the actual useful data transmission was proposed in DE10112844A1. Here, the testing method detects an inactive phase of the data transmission protocol, e.g., via a fieldbus line, in order to transmit a test signal during the inactive phase by means of a testing device without interrupting the transmission protocol. The reflection of the test signal along the transmission line is detected and evaluated.

Unlike WO 2020/104491 A1, most solutions proposed up to now, such as, e.g., also in DE101 12844A1, use a reflection measurement, usually according to the principle of time-domain reflectometry (TDR), for determining the properties of electrical lines by observing the reflected waveforms. An advantage here is that faults can thereby be located. However, these methods are technically very complex and mostly not suitable for an application during operation (on-line).

Therefore, a first object of the present invention is to propose a solution which enables the status of an electrical line to be monitored during operation, wherein the solution is to be able to be implemented with as little effect as possible or without effect on the intended operation and/or with comparatively little effort. This object is achieved independently of each other by a monitoring system according to claim 1, an adapter system according to claim 2 or also the use or the method according to claim 15.

In the case of a generic monitoring system according to the preamble from claim 1, it is proposed for the achievement of the object that two modules are designed to work together in order to determine, during operation, at least one electrical transmission property of the line section to be monitored with respect to a predetermined radio-frequency signal, in particular an RF signal which is independent of the intended usage of the line to be monitored or is not intended to be used as useful signal and is preferably selected to be as free of interference as possible for the usage, among other things with respect to possible interferences. Here, according to a basic idea of the invention, a value relating to the transmission quality of the non-intended RF signal over the line section, in particular with respect to the received signal strength or signal attenuation, is determined and used for the evaluation.

For this, it is first of all provided in particular that the first monitoring module comprises an RF generator or an RF source, which is coupled to the line to be monitored in order to put a predetermined RF signal on the line section to be tested as a separate signal that is independent of the designated usage in the manner of a test signal, e.g., to apply it electrically or couple (feed, insert, impress or the like) it into at least one conductor of the line.

On the other hand, the second module has an RF receiver that is suitable for the RF signal or an RF signal sink, which is coupled to the line to be monitored in order to receive the RF signal from the line section, and that the module or the RF receiver is set up to evaluate properties of the received RF signal in order to determine at least one value relating to the transmission quality over the line section, in particular with respect to the received signal strength or signal attenuation. The second module is preferably set up to output this value over a further connection, in particular a wired or else wireless connection, to a higher-level unit.

The coupling to the line to be monitored can be effected conductively or non-conductively, e.g. capacitively and/or inductively depending on the application case; possibly conductively in the case of data lines, preferably non-conductively in the case of lines carrying supply voltage, e.g., for purposes of a protective insulation.

In the present case, as is generally the case in electrical engineering with radio frequency (RF), first of all the frequency range from approximately 10 kHz up to the THz range is generally referred to as radio frequency (RF) (i.e., not merely the more limited HF definition from radio engineering for short waves or the range between MF radio and VHF radio). In the present case, by radio frequency is meant in particular frequencies in the range of at least 1 MHz up to 10 GHz, in particular also typical radio frequencies. Particularly preferably, one of the permit-free and licence-free ISM bands (Industrial, Scientific and Medical Band) according to ITU Radio Regulations (Art. 5, ed. 2012) can be used.

Furthermore, an adapter system is proposed for monitoring the status of a line during operation having two corresponding modules, which can each be connected in an adapter-like manner to a first end and to a second end, respectively of a line section to be monitored. According to the invention, it is here correspondingly provided that—the modules are designed to work together in order to determine, during operation, at least one electrical RF (radio frequency) transmission property of the line section with respect to a predetermined RF signal, which signal is preferably independent of the intended usage of the line to be monitored, and
the first module comprises an RF generator, which can be coupled to the line to be monitored in order to apply a predetermined RF signal as test signal; and
the second module has an RF receiver, which is coupled to the line to be monitored in order to receive the applied RF signal from the line section, and is set up to evaluate properties of the received RF signal in order to determine at least one value relating to the transmission quality over the line section, in particular with respect to the received signal strength or signal attenuation.

Furthermore, at least the second module can be set up to output this value over a further connection, in particular a wired connection, to a higher-level unit.

The invention is based first of all on the counterintuitive approach of using the line other than as intended for a non-intended RF signal, which can in particular have the form of a likewise counterintuitive radio signal, which is intended for wireless transmission. The invention can provide a radio signal, in particular a radio signal which is intended for wireless data communication, to test a wired conductor. It can be, e.g., a radio signal having a radio-frequency carrier frequency on which information is impressed possibly by modulation, the usage of which is, however, not important for the intended usage of the line.

Furthermore, the invention is based on the knowledge that an unfavourable alignment between the line and the RF signal is not important if a usage of the RF signal for its actual signal function, for instance information transmission, is not intended. The absolute transmission quality of the test signal is not important for the invention.

On the contrary, without wanting to be bound to theory, emission losses on lines having faults, in particular one- or two-wire lines, increase roughly quadratically with the signal frequency. Accordingly, higher-frequency signals are generally suitable for detecting typical signs of abrasion in moving flexible lines, in particular in energy chains, such as, e.g., cross-section changes caused by continuous bending stress, kinks, strand breaks or other faults. However, the signal attenuation can be comparatively low, e.g., in the case of idealized one-wire or two-wire conductors.

In principle, a relative change in the transmission quality of the test signal is monitored and utilized as an indicator of abrasion or wear-related degradation of the line.

In an embodiment it is thus provided that the predetermined RF signal, which is used for the monitoring, is a radio data transmission signal.

Here, the RF units (RF generator and/or RF receiver) can in each case be designed as components of a respective radio transceiver. As a result, e.g., commercially available, inexpensive radio transceivers can be used.

A favourable embodiment provides that the RF generator and the RF receiver are designed as components of an integrated circuit, in particular a radio IC (IC=integrated circuit). The RF units can preferably be present as components of radio ICs, which are structurally identical in both modules, which among other things standardizes the construction and lowers costs.

In such an embodiment, it is preferably provided that both RF generator and RF receiver are designed in each case as components of radio ICs for data transmission according to a commercial wireless protocol or wireless standard which already inherently implement a function for estimating the received signal strength. Examples of such radio ICs are, e.g., ICs or chipsets for WLAN, LoRaWAN, LTE, or similar protocols/standards for wireless data transmission. The actual function for data transmission must not or should not be used, but rather primarily an integrated function for determining the signal quality, in particular for estimating the relative quality of the RF signal or radio signal received over the monitored section. Thus, for example, WLAN/Wi-Fi in the 2.4 GHz frequency band (IEEE 802.11b/g/n) or 5 GHz frequency band (IEEE 802.11a/h and IEEE 802.11 n) provides an RSSI measurement or an RCPI measurement. The RSSI shows the power level which is received. In the case of LoRaWAN, e.g., with a frequency band of approx. 433 to 435 MHz (ISM band region 1) and of 863 to 870 MHz (SRD band) in Europe or frequency band 902 to 928 (fundamental frequency 915 MHz) in North America, an RSSI measurement or the like is typically also already provided as an included function of commercial LoRa-ICs. Other comparable approaches for assessing the received signal strength or the signal attenuation over the monitored line are also within the scope of the invention.

For this, a function, implemented in a protocol- or standard-inherent manner, of a commercial radio IC is preferably used for the data transmission according to a commercial wireless protocol or wireless standard. This avoids, among other things, the costs of complex measurement technology, as is usual in the case of current TDR approaches.

The RF signal used preferably has a frequency spectrum that is as independent as possible of the intended usage of the actual useful application of the line to be monitored, in particular in a significantly higher frequency band, e.g., in particular in a frequency band around a fundamental frequency f in the range of from 1 MHz up to 10 GHz, in particular in the range 100 MHz<f<7 GHz. In this case a carrier frequency for a protocol- or standard-inherent modulation can also/alternatively be in this range. The selection should be made such that the RF signal generates as little interference as possible with the useful signal of the line.

First experiments with the help of an exemplary prototype have shown that an application or insertion of a LoRa radio signal onto an ETHERNET line allows monitoring that is sensitive with respect to wear or abrasion with the help of the RSSI value, without excessive interference of the ETHERNET transmission.

Thus, it can preferably be provided that at least the second module is set up, in particular the RF receiver or the radio IC(s) is/are preconfigured, for an RF attenuation measurement of the received RF signal, in particular for an RSSI measurement. In the case of structurally identical ICs, the suitability is present in both modules, with the result that an interchangeable use is also possible in the case of a suitable design.

In particular, when using conventional radio ICs, these can be coupled or are capable of being coupled to the line section to be monitored by means of an intended antenna connection, for which, if applicable, a suitable coupling unit or coupling circuit is provided.

In an embodiment, both modules comprise a coupling circuit for the galvanic coupling of RF generator or RF receiver to the line section to be monitored. This can advantageously comprise further functional units, in particular:
a first filter element, in particular with a filter characteristic tuned to the RF signal;
a switching element for the selectable coupling to different conductors of a multi-conductor line; and/or
an impedance matching element.

Further advantageous developments of the system or the module are to be taken from the dependent claims 8-14.

The monitoring using the modules is preferably effected continuously during nominal operation, possibly, e.g., time-discretely at predetermined regular or non-regular points in time.

Here, in particular the preferably external further processing of the quality value of the test signal, which is indicative of the transmission quality over the monitored line section, is to be highlighted. For this, the module serving as receiver can transmit the determined value, e.g., an RSSI value, if applicable after conversion into a digital value in any suitable format, to a separate evaluation unit.

In an embodiment it is thus provided that the system has a separate evaluation unit which determines information on the status of the line to be monitored on the basis of the value relating to the transmission quality and, for this, e.g., compares the value with prestored information.

Additionally or alternatively to this, the second module can be connectable or connected over a further connection, in particular a wired or else wireless connection, to a higher-level unit or the evaluation unit.

For this, the evaluation unit can in particular compare the transmission quality value, e.g., a RSSI value, with a prestored tolerance range. The tolerance range is typically application-dependent, among other things, e.g., dependent on line type, line length, connectors used and further parameters. During start-up, the tolerance range can be determined by an initialization and/or over an initial operating period considered to be fault-free and, e.g., stored in the evaluation unit. If, purely by way of example, the RSSI value fluctuated between −52 dBm and −56 dBm (decibel-milliwatts) during start-up after a few movement strokes of an energy chain, then, as tolerance range, a value of +/−2 dBm around these values, i.e. from −50 dBm to −58 dBm, could be regarded as nominally acceptable. Each departure from a predetermined tolerance range can be assessed as a potential bad case. To prevent false-negative results, the decision for a bad case should possibly trigger a response with decision tolerance, e.g., for each integral over a concurrent time window. The response can, e.g., be a maintenance message for predictive maintenance or also a control signal for triggering a system stop for safety purposes.

At present, the monitoring, e.g., of an RSSI value or a similar value, which provides information on received signal strength or signal attenuation, and the comparison thereof with a prestored tolerance range is regarded as a preferred approach.

The prestored tolerance range can, e.g., be programmed in or parametrized from empirical values or can be learned through an initialization process matching the application, wherein other approaches are also possible.

Continuous monitoring during operation of the line guiding device is generally preferred.

The proposed modules can have, in the case of conductive coupling into the monitored line, suitably selected sockets for a detachable plug connection. Since one of the two modules, in particular at the movable consumer, is arranged outside of the energy chain or dynamic line guide, the proposed system can inherently recognize the not uncommonly occurring case of a fault in the connector at the movable connection. Due to movement stress, in practice faults regularly occur which are not by wear in the actual line but by mechanical load, for instance tensile force on one of the wires, which causes the connector at the movable connection to fail. In this case, a deterioration of the transmission can also be inherently involved.

Furthermore, the invention also relates to a method or the use of a system for monitoring the status of a line during operation (on-line) with the method features according to independent claim 15.

In addition to energy chains made of individual links, other types of dynamic line guides are also considered in which lines are dynamically stressed during operation. Purely by way of example, e.g., WO 2016/042134 A1 discloses a flexible line guide for clean room applications, to which the invention is also applicable.

The proposed solution is suitable for monitoring the status of different lines, in addition to data lines, e.g., bus lines also for power supply lines, during operation. In this case, the line can be guided in particular in a dynamic line guide. The concept is applicable to a wide variety of data lines, e.g., ETHERNET (IEEE 802.3), PROFIBUS or other industrial fieldbus types, such as for instance the CAN bus, EIA-485 or the like or other control lines e.g. However, the proposed concept is, unlike in WO 2020/104491 A1, also readily applicable to supply lines for pure power supply.

In particular, the proposed solution allows for predictive or preventive maintenance to prevent failures.

Further advantageous features and effects of the invention are explained below, without limiting the generality of the above, with reference to preferred embodiment examples with reference to the accompanying drawings. There are shown in:

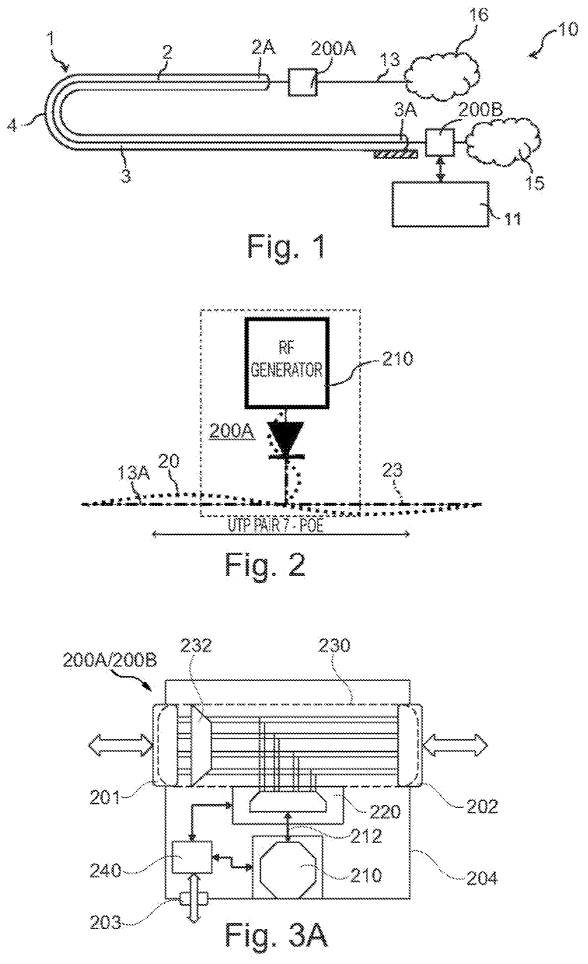

FIG. 1: a schematic diagram in side view of an energy chain with a monitoring system according to the invention according to a first embodiment example;

FIG. 2: a schematic diagram of a module for applying an RF signal to a line;

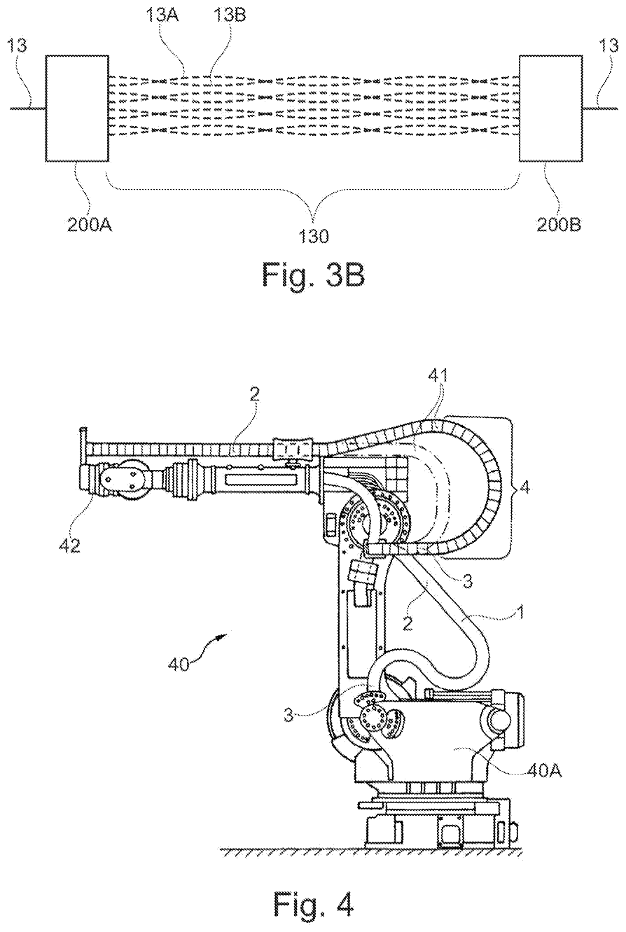

FIG. 3A: a schematic diagram of an embodiment example of a module according to the invention for a monitoring system, in particular according to FIG. 1;

FIG. 3B: a schematic diagram of a system with two modules according to the concept from FIG. 3A for a monitoring system, in particular according to FIG. 1;

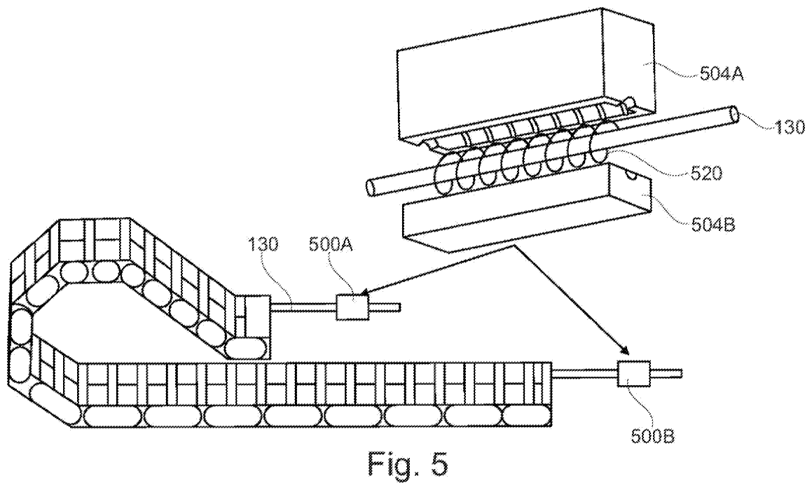

FIG. 4: as application example, a side view of an industrial robot having a spatially deflectable energy chain which can be equipped with a monitoring system according to FIG. 1; and

FIG. 5: a schematic diagram in side view of an energy chain with a monitoring system according to the invention according to a second embodiment example with inductive coupling.

In FIG. 1, a schematically shown energy chain, as an example of a dynamic line guiding device, is generally designated by 1. The energy chain 1 is used for the protected guiding of electrical lines (not shown in more detail) to a movable consumer. Between a moving run 2, here the upper run, and a stationary run 3, here the lower run, the energy chain 1 forms an accompanying deflection curve 4 with a predefined curvature. The deflection curve 4 has a predefined, minimum radius of curvature to avoid line breaks. The energy chain 1 thus guarantees that the guided lines do not fall below the permissible radii of curvature. The energy chain 1 typically forms an inner guide channel in which an application-dependent number and type of lines are guided. The design of the energy chain 1 is not decisive for the invention, e.g., all dynamic line guides known per se come into consideration, if applicable also those without individual chain links, e.g., band-like line packets or those guided in a flexible hose.

FIG. 1 shows purely by way of example a typical arrangement with an energy chain 1 that is movable linearly and in one plane, e.g., horizontally. In FIG. 1, the moving run 2 ends at a first connection end 2A, e.g., in an end link, which is fastened to a driver of a movable machine part (not shown). The stationary run 3 ends at a second connection end 3A, e.g., in an end link, which is fastened to a fixed point of the machine or system, as indicated schematically in FIG. 1. FIG. 4 shows another type of energy chain, frequently used on industrial robots, with spatially deflectable links, i.e., a three-dimensionally movable energy chain.

FIG. 1 schematically shows as one aspect of the invention a monitoring device which is generally denoted by 10. The monitoring device 10 comprises a first module 200A and a second module 200B, which comprise RF (radio frequency) units according to the invention, as will now be described in more detail.

The modules 200A, 200B work together in order to determine, during operation of the line 13 or of the machine or system powered by it, at least one electrical RF (radio frequency) transmission property of a line section 130, guided in the energy chain 1 (FIG. 3B), of a line with respect to a predetermined RF signal, which is coupled onto the line section 130 as test signal especially for this purpose.

FIG. 2 shows very schematically the first module 200A, with an RF generator (RF=radio frequency), which places or couples (in) a predetermined RF signal 20, schematically represented with a dotted line in FIG. 2, onto a monitored single wire 13A here. The signal is independent of the signals 23 used in the intended usage of the line 13, schematically represented with a dot-dashed line on the single wire 13A, and preferably generates minimal or no interference worth mentioning here. The actual operating signal 23 can, e.g., be, purely by way of example, an ETHERNET signal, a signal according to any desired industrial bus, or also a signal of a non-packet-based bus system, or any desired digital or analogue control line or measuring line, e.g., for an actuator (drive, motor, or the like) or any desired sensor, e.g., a rotary encoder.

The invention is in principle also applicable to power supply lines. As FIG. 2 schematically shows, the first module 200A has an RF generator 210 which is coupled to the line 13 to be monitored, here, e.g., a single wire 13A, in order to additionally apply the predetermined RF signal, as a kind of test signal, to the single wire 13A. In principle, in particular in the case of data lines, every suitable conductive or, in particular in the case of live power lines, a non-contact coupling, in particular inductive coupling, also comes into consideration.

As FIG. 3B shows in more detail, the second module 200B is connected at the other end of the line section 130 to be monitored, e.g., by a connector-socket connection. The modules can be made adapter-like, with input and output sockets suitable for the monitored line, e.g., RJ45 sockets for a CAT7-ETHERNET line, or other suitable sockets. FIG. 3B schematically illustrates several single wires 13A, 13B etc., which are present here by way of example as four pairs of twisted pair lines, but are application specific, i.e., depend on the line 13 to be monitored.

The second module 200B has an RF receiver, e.g., in the form of an RF transceiver 210 (cf. FIG. 3A), which is coupled to the line to be monitored, and taps or receives the test signal or RF signal 20 from the line section 130. The second module 200B is in particular set up or configured to determine a value which represents the received quality of the test signal, in particular the signal strength or the signal attenuation of the received RF signal 20 at the movable connection of the line 13 with the module 200. For this, e.g., the RF transceiver 210 is set up in the second module 200B to evaluate properties of the received RF signal, and thus to generate, for the transmission quality over the line section 130, an indicative value for the signal strength or the signal attenuation.

As FIG. 1 shows, the second module 200B is preferably set up to output at least this value over a further connection, e.g., a wired USB connection, which at the same time supplies the module 200B electrically, to a higher-level monitoring unit 100, e.g., to a module which is available under the trade name “i.Cee:plus” or “iCom” from igus GmbH, 51147 Cologne. The monitoring unit 100 can in particular be set up to communicate with systems engineering in the desired application or configured with a cloud solution.

In an embodiment, a structurally identical integrated circuit for radio data transmission, in short radio IC 210, is used in both modules 200A, 200B and is usable both as transmitter (Tx) or RF generator and as receiver (Rx). Thus, RF generator and RF receiver are preferably implemented by the transceiver (Trx) of such a radio IC 210.

Preferably, a radio IC 210 for a commercial radio standard in the ISM band, e.g., LoRaWAN (Long Range Wide Area Network: see https://lora-alliance.org/) is used with RSSI measurement or similar. A WLAN IC or chipset, in particular in accordance with Wi-Fi or a standard of the IEEE 802.11 family, also comes into consideration. Any radio IC 210 which has an RSSI (Received Signal Strength Indicator) or an RSSI-similar function, e.g., RCPI (Received Channel Power Indicator) according to IEEE 802.11 preferably comes into consideration. Thus, the receiver-side radio IC 210 is inherently suitable in the second module 200B, and at low cost, to provide the desired value about the received signal strength or the signal attenuation, in particular as digital output value according to the manufacturer's specification of the radio IC 210. The RF receiver can output the value in any desired format, e.g., also as an analogue voltage at a connection.

In the case of some commercial radio ICs 210, the RSSI is diverted, e.g., in the intermediate frequency stage (IF) ahead of the IF amplifier. The RSSI output can then be provided as an analogue DC level by the IC and, e.g., externally converted into a digital value. Any comparable analogue value which a suitable radio IC 210 delivers as the result of an integrated received field strength measurement can be expressed and utilized, e.g., device-dependently scaled and converted, as an RSSI value or as a dimensionless power level in the unit dBm or in ASU (Arbitrary Strength Unit) or the like. Such an analogue value from the IF stage in the radio IC 210 can also be sampled by an internal analogue-to-digital converter (ADC) in the radio IC 210 which makes the resulting values available digitally via an interface, e.g., a peripheral processor bus. The specific type of the provision and the value is not important.

The invention can in principle advantageously use any suitable type of a sufficiently deterministic determination, estimation or measurement, in particular with respect to the quality of the received test signal, e.g., the signal strength or signal attenuation or received field strength. The usage of commercial radio ICs 210 with an already integrated function is particularly cost-effective for this, such as, e.g., the RSSI determination in the case of a LoRaWAN IC or the RCPI determination of a Wi-Fi IC. Typically, the value is in a range of <0 dBm (ideal value of loss-free transmission) up to −100 dBm ([almost] no signal reception) on a logarithmic scale. Other radio standards also provide such functions, e.g., LTE.

FIG. 3A illustrates a hardware implementation, which is usable both as first module 200A on the transmitter side and as second module 200B on the receiver side. Here, the modules 200A and 200B are in particular designed to be structurally identical in terms of hardware but possibly differently configured or programmed in terms of software, in particular as transmitter (Tx) and as receiver (Rx) with evaluation function or the quality of the received signal.

Accordingly, the radio IC 210 used, e.g., a LoRaWAN IC, is coupled by means of its antenna connection 212 to the line section 130 to be monitored. For the coupling, a coupling circuit 220 is provided in module 200A, 200B, here e.g., for the galvanic coupling of the antenna connection 212 to the line section 130 to be monitored, in particular to one or optionally one of several single wires 13A, 13B etc.

A first filter, or first filter element, can be provided in the coupling circuit 220, in particular with a filter characteristic tuned to the RF signal 20, with the result that the smallest possible portion or none of the intended signals 23 arrive at the antenna connection 212. The filter element can, e.g., be set up as a steep-edge π filter or bandpass filter on the radio frequency band of the RF signal 20 and preferably be implemented in analogue technology with discrete components. The coupling circuit 220 can have, if applicable, a switching unit or a switching element for the selectable or adjustable coupling to different conductors or wires 13A, 13B etc. (cf. FIG. 3B) of the line section 130, in particular if the functionality of all lines has to be monitored. If necessary, at least one impedance matching element can furthermore be provided for at least an improved matching between wires 13A, 13B etc. and the antenna connection 212.

Generally preferably, irrespective of the type of coupling used, i.e., e.g., also in the case of inductive coupling, a suitable decoupling filter circuit is provided, which suppresses all parasitic, in particular line-borne, or undesired, propagation paths of the test signal or RF signal 20 and limits the test signal to the monitored line section 130.

FIG. 3A furthermore shows a circuit component or device 230 for looping through the line 13 or its individual conductors 13A, 13B for the purpose of intended usage of the line to be monitored during the monitoring. A filter element 232 that limits the transmission of the RF signal to one of the two connections 201, 202 for the line 13 substantially on the line section 130 to be monitored is preferably included in this circuit component 230. For this, the filter element 232 can be designed, e.g., as a band rejection filter or band stop filter, which does not allow the frequency band of the pseudo radio signal or test signal 20 to pass into the parts 15, 16 of the customer system as much as possible.

The module preferably has as comprehensive as possible a shielding implemented in or with the housing 204 for as complete as possible a reduction of radio emissions by the radio IC 210, with the result that an unwanted air connection between modules 200A, 200B is ruled out as far as possible. The shielding of the housing 204 also prevents, e.g., external radio signals from interfering and distorting the diagnosis results temporarily or permanently.

For the control and/or signal evaluation or further processing of the values from the radio IC 210, the module can furthermore have a control unit, in particular a programmable integrated circuit, such as a microprocessor 240 or the like. This can be connected, via a further suitable connection 203 for the purpose of data connection, to the evaluation unit 100, e.g., via a USB connection for controlling the RF generator or RF receiver in the radio IC 210. Via microprocessor 240 and connection 203, an optional setting can, e.g., also be effected on transmitter behaviour, for use as first module 200A, or receiver behaviour and evaluation, for use as second module 200B. As the architecture in FIG. 3A reveals, the module 200A/200B shown is optionally usable as transmitter or receiver, for which only a reverse use of the connections (exchange system side/energy chain side) and corresponding programming is required.

The power supply (not shown) can be effected either via the monitored line 13 or also, e.g., via the USB connection 203, depending on whether the module is used as transmitter module 200A or receiver module 200B, since the receiver module 200B can preferably be connected via the connection 203 to the separate higher-level evaluation unit 100 and, e.g., can be mounted with it in a control cabinet.

The evaluation unit 100 receives the current value relating to the transmission quality, e.g., RSSI value, continually from the module 200B or from the radio IC 210, possibly via the control unit 240 and the connection 203 or alternatively via a further external wireless connection, not shown, and compares it, e.g., to prestored reference information, preferably with a tolerance range, and/or passes this value on to a further higher-level computer control which evaluates the values and, if applicable, can intervene in the system, e.g., triggers an emergency stop.

The evaluation unit 100 or another unit preferably separated from the compact cost-effective modules 200A, 200B determines status information on the status of the line to be monitored on the basis of the value received relating to the quality of reception at the module 200B, which is informative about undesirable physical changes in the monitored line section 130 as well as possibly the plug connections thereof with the connections 201 or 202.

In an embodiment example, the evaluation unit 100 itself evaluates RSSI values by comparison with a previously stored tolerance range. If values fall below or exceed the tolerance range, the evaluation unit 100 issues a warning or error message to a higher-level monitor, preferably via a separate channel. Predictive maintenance is hereby made possible since a deterioration in the quality of reception at the receiver module 200B usually occurs before the line 13 completely fails.

As an exemplary application for a monitoring device 10, FIG. 4 shows a jointed-arm robot 40, e.g., for the fully automatic handling of workpieces in a manufacturing process. From the fixed base 40A of the jointed-arm robot, e.g., a first linearly movable energy chain 1, similar to FIGS. 1-3, here leads to a swivel joint from which a spatially deflectable second energy chain 41 (e.g., according to WO 2004/093279 A1) leads further to the end effector 42 or end-side robot tool. At the end effector 42, a number of actuators and sensors are typically provided that are already suitable for a common fieldbus protocol or, e.g. the PROFINET protocol.

These actuators and sensors can also be powered via a line 13, which is guided with a section 130 (FIG. 3B) in the second energy chain 41. Thus, a monitoring device 10 according to the concept from FIGS. 1-2 and FIGS. 3A-3B can monitor the wear status of at least one or, if applicable, all data and/or signal lines which are guided by the energy chains 1, 41, in particular by the energy chain 41. For this, only inexpensively implementable modules 200A, 200B and possibly an evaluation unit 100, which can also be implemented in the form of a software module on an already available computer, are required. An already available control unit or monitoring unit can also be used as evaluation unit 100.

If transceivers are used, the relevant quality value of the test signal can possibly be sent back from the receiver module 200B, in a transmitting mode, to the transmitter module 200A. Thus, in reverse to what is shown in FIG. 1, the receiver module 200B can also be arranged on the moving machine or system part, and can send back, e.g., RSSI values continuously, possibly via the test signal 20, to the transmitter module 200A, which is then in turn connected to the evaluation unit 100.

The proposed system for monitoring the line status thus provides an inexpensive solution for supporting predictive maintenance and/or for reducing or avoiding downtimes. The invention enables the maximum use, among other things, of more vulnerable and, if possible, also cost-intensive data lines, special lines, or the like, with respect to their possible service life, i.e. to avoid an unnecessary early replacement.

The solution is furthermore also applicable to power supply lines.

FIG. 5 shows a preferred embodiment example with two modules 500A, 500B for the inductive coupling in or coupling out of the test signal 20 (FIG. 2) on the line section 130 to be monitored of a line 13, which is guided in an energy chain 1 (cf. FIG. 1).

For this, according to FIG. 5, in each module 500A, 500B, an induction coil 520 is wound around a respective end area of the line section 130 and couples the desired test signal 20 inductively in or out. Each module 500A, 500B has two conjugated or mutually matching half-shells 504A, 504B, which provide as comprehensive as possible a shielding for as complete as possible a reduction of radio emissions via an unwanted air connection or radio link between the modules 500A, 500B. This also prevents, e.g., external radio signals from interfering.

In a half-shell 504A, in each case a circuit is provided in a corresponding design to FIG. 3A for coupling in or coupling out of the test signal 20. The circuit (not shown in more detail) also has a suitable radio IC 210 (cf. FIG. 3A), to the frequency band of which, e.g., the length of the induction coil 520 is matched. The induction coil 520 is conductively connected to the radio IC 210. In contrast to FIG. 3A, in FIG. 5 the coupling in and out of the test signal 20 into the line 13 is affected purely inductively, however, i.e. without change at the line 13 to be tested.

The two half-shells 504A, 504B further have form grooves in order to guarantee a predetermined winding geometry, in particular a constant winding pitch length and the same radial distance between the induction coil 520 and the line 13. In FIG. 5, coupling in and out of the test signal 20 are also preferably carried out via structurally identical units or modules 500A, 500B.

An inductive coupling with the line section 130 can be implemented in any suitable design. Alternatively to the design shown in FIG. 5, this can also be implemented, e.g., in the manner of a current transformer or a single winding transformer. Here, in each case a magnetizable toroidal core, e.g., a ferrite core consisting of two core parts, e.g., ring halves (not shown), can be arranged in each module 500A, 500B around the end area of the line section 130. With the toroidal core, the induction coil 520 can work together in the manner of an inductive current transformer or core balance transformer as a secondary coil, wherein the line section 130 represents the (single) primary winding in the ideal circuit diagram. A transmission of the test signal between the induction coils 520, which makes it possible to monitor the status of the line section 130, can also be achieved in this way.

An inductive coupling, for instance in accordance with FIG. 5, is basically to be preferred. An important advantage of inductive coupling is that modules 500A, 500B can be attached without any change or without intervention in the line to be monitored by simply winding around or surrounding at the desired places on both sides of the energy chain 1. The inductive coupling, e.g., in accordance with FIG. 5, is also suitable in particular for live power lines in which for safety reasons interventions are rather not desired.

In the case of a suitable selection of the radio IC 210, the invention enables an inexpensive solution without complex technology which is usable during operation without interfering with the intended usage of the line 13, e.g., transmitted data. The test signal 20 can possibly be used only for testing the transmission quality thereof, i.e., must in particular not be used for the actual transmission of messages or information.

On the other hand, signals of the monitored line 13 themselves intended for the actual application are in particular not used for monitoring purposes. Furthermore, a continual or continuous checking/monitoring of the status of the line is made possible with comparatively low performance.

Various metrics can be used for testing the quality of reception in the receiver module as long as they are able to provide information about the current status of the line section.

The system or method according to the invention determines data transmission properties of the lines during operation by means of RF technology. There is thus no longer the need for additional conductors or measuring wires or sacrificial wires. The modules 200A, 200B or 500A, 500B, respectively form insertion adapters at the start and end of the area to be monitored, in particular through the line guiding device 1, 42. A compact design of the modules 200A, 200B or 500A, 500B, respectively, enables easy retroactive installation. Subsequently, the detected values are further processed during operation. As the transmission properties begin to deteriorate, this can be considered immediately as an indicator for a timely line replacement. System downtimes can also be prevented through this intelligent status monitoring of the entire moving line including plug connectors.

### LIST OF REFERENCE NUMBERS

### FIG. 1

1 line guiding device (energy chain)
2 moving run
2A first connection end
3 stationary run
3A second connection end
4 deflection curve
10 monitoring device
100 monitoring unit
13 bus line/supply line
first area (customer network/bus)
16 second area (customer network/bus)
200A first module
200B second module

### FIG. 2 and FIGS. 3A-3B

13 line
13A, 13B single wires (e.g., twisted pair)
20 radio signal
23 useful signal
130 monitored line section
200A first module
200B second module
201, 202, 203 connections (sockets, e.g., RJ45).
204 housing (with shielding)
210 radio IC (e.g., LoRaWAN)
212 antenna connection
220 coupling circuit
230 pass band circuit
232 filter
240 control unit (microprocessor)

### FIG. 4

1 first energy chain (linearly movable)
2 first run
3 second run
4 deflection curve
jointed-arm robot
40A base
41 second energy chain (spatially deflectable)
42 end effector

### FIG. 5

13 line
130 monitored line section
500A first module
500B second module
504A first half-shell
504B second half-shell
520 induction coil/antenna

1. A monitoring system for monitoring the status of a line which is guided by a line guiding device, in particular an energy chain, comprising:
a movable line guiding device (1; 41) for guiding a line between a first connection point and a second connection point movable relative thereto, wherein the line guiding device (1; 41) has at least one movable section and at least one line (13), which is guided by the line guiding device (1; 41) with a line section (130) to be monitored; and
a monitoring device (10), which has a first module (200A) and a second module (200B), which are in each case provided on both sides of the line section to be monitored, and
wherein the first and second modules (200A, 200B) are configured to work together in order to determine, during operation, at least one electrical transmission property of the line section (13A; 13B) with respect to a predetermined radio frequency (RF) signal; and
the first module (200A) comprises an RF generator for generating a predetermined RF signal as a test signal, which test signal is independent of the intended use of the line (13) to be monitored and which is not used as payload signal, wherein the RF generator is coupled to the line (13) to be monitored in order to couple or bring onto the line section (130) the predetermined RF signal as test signal; and
the second module (200B) comprises an RF receiver, which is coupled to the line to be monitored, in order to couple out or to receive the RF signal from the line section (130), and is set up to evaluate properties of the received RF signal in order to determine at least one value relating to the transmission quality over the line section (130).

2. An adapter system for monitoring the status of a line during operation, comprising a first module (200A) and a second module (200B), which can each be connected or coupled in an adapter-like manner to a first end or to a second end, respectively, of a line section (130) to be monitored;
the first and second modules (200A, 200B) are configured to work together in order to determine, during operation, at least one electrical RF (radio frequency) transmission property of the line section (130) with respect to a predetermined RF signal;
the first module (200A) comprises an RF generator (210) for generating a predetermined RF signal as test signal, which test signal is independent of the intended use of the line (13) to be monitored and which is not used as payload signal, wherein the RF generator can be coupled to the line (13) to be monitored in order to apply the predetermined RF signal as a test signal; and
the second module (200B) comprises an RF receiver (210), which is coupled to the line to be monitored in order to receive the applied RF signal from the line section (130), and is set up to evaluate properties of the received RF signal in order to determine at least one value relating to the transmission quality over the line section.

3. The system according to claim 1, wherein
the predetermined RF signal (20) is a radio data transmission signal, and/or
the RF generator and RF receiver are components of a respective radio transceiver (210).

4. The system according to claim 3, wherein
that RF generator and RF receiver are designed in each case as components of an integrated circuit, or
that RF generator and RF receiver are components of identical radio ICs (210) in both the first and second modules (200A, 200B).

5. The system according to claim 3, wherein
at least the second module (200B) is configured for a measurement of the strength of the received RF signal (20).

6. The system according to claim 1, wherein the RF generator and the RF receiver are coupled or can be coupled to the line section to be monitored by means of an intended antenna connection (212).

7. The system according to claim 6, wherein both the first and second modules (500A, 500B) comprise a coupling circuit for the inductive coupling to the line section to be monitored, wherein the coupling circuit in particular has in each case a coupling coil (520), which
can be wound or is wound around an end area of the line section (130) to be monitored; or
is coiled around a magnetizable toroidal core that is arranged or can be arranged around an end area of the line section to be monitored
in order to inductively couple the test signal into or out of the line section to be monitored and is conductively connected to the RF generator or RF receiver, respectively.

8. The system according to claim 6, wherein both the first and second modules (200A, 200B) comprise a coupling circuit (220) for the galvanic coupling of RF generator or RF receiver, respectively, to the line section to be monitored, wherein the coupling circuit comprises:
a first filter element with a filter characteristic tuned to the RF signal;
a switching element for the selectable coupling to different conductors of the line; and/or
an impedance matching element.

9. The system according to claim 8, wherein each of the first and second modules (200A, 200B) comprises at least one filter element (232), which substantially limits the transmission of the RF signal to the line section to be monitored.

10. The system according to claim 1,
further comprising a separate evaluation unit (100) which determines information on the status of the line (13) to be monitored on the basis of the value relating to the transmission quality by comparing the value with prestored reference information; and/or
wherein at least the second module (200B) can be connected or is connected over a further connection to a higher-level unit or the evaluation unit (100).

11. The system according to claim 7, each of the first and second modules (200A, 200B) has shielding (204) for the reduction of radio emissions, wherein the shielding is implemented with two half-shells sealable around an end area of the line section to be monitored.

12. The system according to claim 1, wherein each of the first and second modules (200A, 200B; 500A, 500B) has-comprises a device (520) for coupling to the line to be monitored and/or one device (230) for looping through the line or its individual conductors (13A, 13B) for the purpose of intended usage of the line (13) to be monitored during the monitoring.

13. The system according to claim 8, wherein the coupling (220) of the module to the line section to be monitored is configured for conductive coupling or as non-contact coupling, in particular inductive coupling.

14. The system according to claim 1, wherein each of the first and second modules comprises a control unit (240) configured to control the RF generator or the RF receiver (210).

15. A method for monitoring the status of a line during operation, with a system comprising a first module and a second module, which are located at a first end or at a second end, respectively, of a line section to be monitored, and the method comprising:
determining with the first and second modules working together, during operation, at least one electrical transmission property of the line section with respect to a predetermined RF signal, which is independent of the intended usage of the line to be monitored;
generating with the first module the predetermined RF signal as a test signal, which the test signal is independent of the intended use of the line (13) to be monitored and which is not used as payload signal, and the first module brings onto or couples into the line section the predetermined RF signal as the test signal; and
receiving with the second module the RF signal from the line section and evaluating properties of the received RF signal in order to determine an indicator value relating to the transmission quality of the received RF signal, wherein this indicator value is used for the evaluation of the monitored line status.

16. The system according to claim 2, wherein
the predetermined RF signal (20) is a radio data transmission signal, and/or
the RF generator and RF receiver are components of a respective radio transceiver (210).

17. The system according to claim 2, wherein the RF generator and the RF receiver are coupled or can be coupled to the line section to be monitored by means of an intended antenna connection (212).

18. The system according to claim 2,
further comprising a separate evaluation unit (100) which determines information on the status of the line (13) to be monitored on the basis of the value relating to the transmission quality by comparing the value with prestored reference information; and/or
wherein at least the second module (200B) can be connected or is connected over a further connection to a higher-level unit or the evaluation unit (100).

19. The system according to claim 2, wherein each of the first and second modules (200A, 200B; 500A, 500B) comprises a device (520) for coupling to the line to be monitored and/or one device (230) for looping through the line or its individual conductors (13A, 13B) for the purpose of intended usage of the line (13) to be monitored during the monitoring.

20. The system according to claim 2, wherein each of the first and second modules comprises a control unit (240) configured to control the RF generator or the RF receiver (210).
